(19) United States
(12) Patent Application Publication
(10) Pub. No.: US 2017/0063363 A1
(43) Pub. Date: Mar. 2, 2017

(54) COMPARATOR, ELECTRONIC CIRCUIT, AND METHOD OF CONTROLLING COMPARATOR

(71) Applicant: FUJITSU LIMITED, Kawasaki-shi (JP)

(72) Inventor: Takumi Danjo, Kawasaki (JP)

(73) Assignee: FUJITSU LIMITED, Kawasaki-shi (JP)

(21) Appl. No.: 15/231,985

(22) Filed: Aug. 9, 2016

(30) Foreign Application Priority Data
Aug. 24, 2015 (JP) 2015-164854

(51) Int. Cl. H03K 5/26; H03K 3/037

(52) U.S. Cl. CPC H03K 5/26; H03K 3/037

(57) ABSTRACT

A comparator includes an input-stage circuit configured to operate in synchronization with a clock signal and to produce two voltages at two nodes, respectively, such that which one of the two voltages is greater than the other is responsive to which one of two input signals is greater than the other, a positive-feedback circuit configured to operate in synchronization with the clock signal and to produce, through positive feedback, two output signals responsive to which one of the two voltages at the two nodes is greater than the other, and an adjustment circuit coupled to the two nodes, and configured to change, in response to a setting value, speed at which voltages at the two nodes change.

### CROSS-REFERENCE TO RELATED APPLICATIONS

The present application is based upon and claims the benefit of priority from the prior Japanese Patent Application No. 2015-164854 filed on Aug. 24, 2015, with the Japanese Patent Office, the entire contents of which are incorporated herein by reference.

### FIELD

The disclosures herein relate to a comparator, an electronic circuit, and a method of controlling a comparator.

### BACKGROUND

A comparator used in an AD converter circuit, a high-speed interconnect circuit, or the like has the comparator output thereof becoming valid only during a specific time period that is specified by a clock signal. A comparator operating in synchronization with a clock signal is referred to as a dynamic comparator, for which an input signal is supplied also in synchronization with the clock signal. A dynamic latch comparator utilizes a configuration which performs regeneration in synchronization with a clock signal by use of a positive feedback such as cross-coupling.

The dynamic latch comparator includes an input stage having a differential transistor pair and serving as an amplifier, and also includes a positive-feedback unit configured to amplify the output of the input stage through positive feedback. The input stage and the positive-feedback unit operate in synchronization with a clock signal. The positive-feedback unit is reset during a reset period, and is activated during an amplification period (i.e., regeneration period). In this amplification period, the positive-feedback unit produces two output signals, such that which one of these output signals is greater than the other is responsive to the result of comparison between the two input signals that are applied to the input stage.

A clock signal may be input into the dynamic latch comparator through multiple stages of buffers. In such a case, the characteristics of these buffers may change, depending on the process condition, the operating temperature, the power-supply voltage, etc., resulting in fluctuation in the timing of edges of the clock signal applied to the comparator. The dynamic latch comparator is designed to produce a proper comparison operation when typical clock-edge timing is used. Under the condition in which the clock edge timing is extremely advanced or extremely delayed, the dynamic latch comparator is unable to perform a proper comparison operation, and may thus produce an erroneous comparison result.

In order to enable a proper comparison operation utilizing proper edge timing, a phase adjuster or delay circuit may be used to adjust the phase of the clock signal. However, a phase adjuster has large circuit size, and is thus not preferable from the viewpoint of power consumption and device size. A delay circuit, on the other hand, adjusts a resistance value and/or a capacitance value to control the timing of rising edges and falling edges of the clock signal, thereby ending up turning the rising edges and falling edges of the clock signal into gentler slopes. In the case of gentle-slope clock edges, the occurrence of noise in the power supply voltage causes a greater displacement of an edge position in the temporal axis than in the case of steep-slope clock edges. Jitters are thus more likely to affect comparison operations. Moreover, the capacitance affecting the rising edges of the clock signal may be different from the capacitance affecting the falling edges of the clock signal, which gives rise to the problem that the duty cycle deviates from a desired value.

### [Patent Document 1] Japanese Laid-open Patent Publication No. 2014-96769

### [Patent Document 2] Japanese National Publication of International Patent Application No. 2013-526102

### [Patent Document 3] Japanese Laid-open Patent Publication No. 2003-69394

### SUMMARY

According to an aspect of the embodiment, a comparator includes an input-stage circuit configured to operate in synchronization with a clock signal and to produce two voltages at two nodes, respectively, such that which one of the two voltages is greater than the other is responsive to which one of two input signals is greater than the other, a positive-feedback circuit configured to operate in synchronization with the clock signal and to produce, through positive feedback, two output signals responsive to which one of the two voltages at the two nodes is greater than the other, and an adjustment circuit coupled to the two nodes, and configured to change, in response to a setting value, speed at which voltages at the two nodes change.

According to an aspect of the embodiment, a method is provided for controlling a comparator, which includes an input-stage circuit configured to operate in synchronization with a clock signal and to produce two voltages at two nodes, respectively, such that which one of the two voltages is greater than the other is responsive to which one of two input signals is greater than the other, a positive-feedback circuit configured to operate in synchronization with the clock signal and to produce, through positive feedback, two output signals responsive to which one of the two voltages at the two nodes is greater than the other, and an adjustment circuit coupled to the two nodes, and configured to change, in response to a setting value, speed at which voltages at the two nodes change. The method includes causing the two input signals to alternate between High and Low at frequency equal to a frequency of the clock signal, and adjusting the setting value in response to the two output signal.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a drawing illustrating an example of the configuration of an electronic circuit including a comparator;

FIG. 2 is a drawing illustrating an example of the configuration of a dynamic latch comparator;

FIG. 3 is a drawing illustrating an example of the operation of the dynamic latch comparator illustrated in FIG. 2;

FIG. 4 is a drawing illustrating another example of the configuration of the dynamic latch comparator;

FIG. 5 is a drawing showing yet another example of the configuration of the dynamic latch comparator;

FIG. 6 is a drawing illustrating an example of a more specific configuration of the dynamic latch comparator illustrated in FIG. 2;

FIG. 7 is a drawing illustrating an example of the operation of the dynamic latch comparator illustrated in FIG. 6;

FIG. 8 is a drawing illustrating another example of a more specific configuration of the dynamic latch comparator illustrated in FIG. 2;

FIG. 9 is a drawing illustrating another example of the configuration of the dynamic latch comparator;

FIG. 10 is a drawing illustrating an example of the configuration of the dynamic latch comparator that performs calibration;

FIG. 11 is a drawing illustrating an example of the calibration operation of the dynamic latch comparator; and

FIG. 12 is a drawing illustrating an example of input signals at the time of calibration.

### DESCRIPTION OF EMBODIMENTS

In the following, embodiments of the invention will be described with reference to the accompanying drawings. In these drawings, the same or corresponding elements are referred to by the same or corresponding numerals, and a description thereof will be omitted as appropriate.

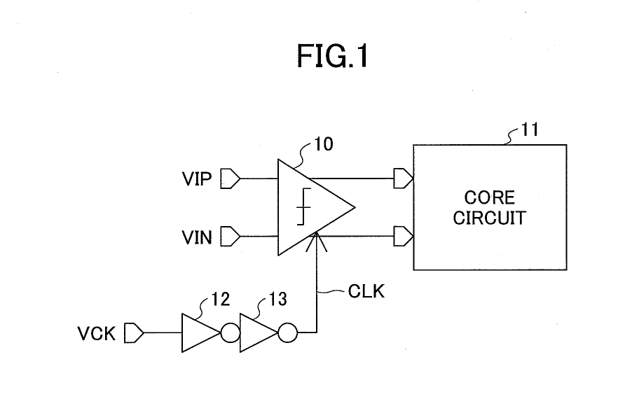

FIG. 1 is a drawing illustrating an example of the configuration of an electronic circuit including a comparator. The electronic circuit illustrated in FIG. 1 includes a dynamic latch comparator 10, a core circuit 11, and buffer circuits 12 and 13. The dynamic latch comparator 10 includes an input-stage circuit having a differential transistor pair and serving as an amplifier, and also includes a positive-feedback circuit configured to amplify the output of the input-stage circuit through positive feedback. In FIG. 1, boundaries between functional or circuit blocks illustrated as boxes basically indicate functional boundaries, and may not correspond to separation in terms of physical positions, separation in terms of electrical signals, separation in terms of control logic, etc. Each functional or circuit block may be a hardware module that is physically separated from other blocks to some extent, or may indicate a function in a hardware module in which this and other blocks are physically combined together.

A clock signal VCK is applied to the dynamic latch comparator 10 as a clock signal CLK through the buffer circuits 12 and 13. The input-stage circuit and the positive-feedback circuit of the dynamic latch comparator 10 operate in synchronization with the clock signal CLK. The positive-feedback circuit is reset during a reset period, and is activated during an amplification period (i.e., regeneration period). In this amplification period, the positive-feedback circuit produces two output signals, such that which one of these two output signals is greater than the other is responsive to the result of comparison between two input signals VIP and VIN that are applied to the input-stage circuit.

The core circuit 11 receives the output signals from the dynamic latch comparator 10 to perform designed operations. The electronic circuit illustrated in FIG. 1 may be an AD converter circuit or a high-speed interconnect circuit. The input signals may be analog signals subjected to AD conversion, or may be transmission signals transmitted from a transmission side. The electronic circuit may include a plurality of dynamic latch comparators 10. The clock signal VCK may be supplied from an external source, or may be supplied from a clock generating circuit such as a PLL circuit embedded in the electronic circuit illustrated in FIG. 1. The core circuit 11 may include a clock generating circuit or a circuit for calibration as will be described later.

The characteristics of the buffer circuits 12 and 13 may vary depending on the process conditions, the operating temperature, the power supply voltage, or the like, so that the timing of edges of the clock signal applied to the dynamic latch comparator 10 may fluctuate. The dynamic latch comparator 10 includes a timing control unit for ensuring that a correct comparison result is produced even when the timing of clock signal edges is displaced.

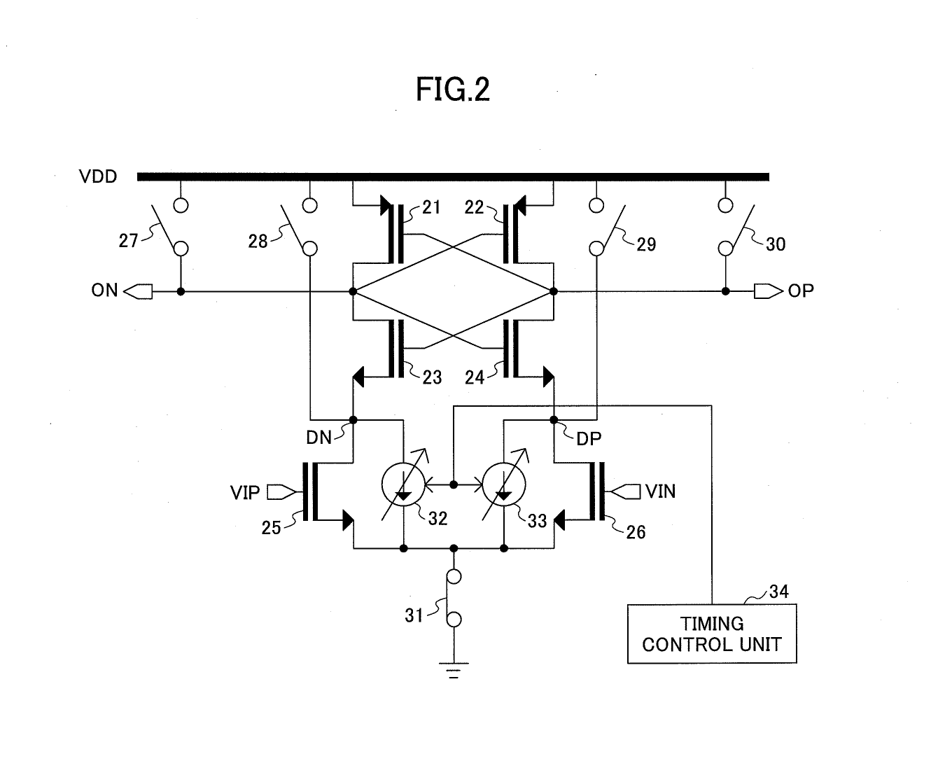

FIG. 2 is a drawing illustrating an example of the configuration of the dynamic latch comparator 10. The dynamic latch comparator 10 illustrated in FIG. 2 includes PMOS transistors 21 and 22, NMOS transistors 23 through 26, switch circuits 27 through 31, current-source circuits 32 and 33, and a timing control unit 34. The switch circuits 27 through 30 become conductive in the case of the clock signal CLK (see FIG. 1) being Low, and become nonconductive in the case of the clock signal CLK being High. The switch circuit 31 becomes nonconductive in the case of the clock signal CLK being Low, and becomes conductive in the case of the clock signal CLK being High. The switch circuits 27 through 30 may be PMOS transistors, for example, and the switch circuit 31 may be an NMOS transistor, for example.

As was previously described, the dynamic latch comparator 10 includes the input-stage circuit and the positive-feedback circuit. The input-stage circuit includes the NMOS transistors 25 and 26 and the switch circuit 31. The NMOS transistors 25 and 26 has the source node thereof coupled to a common node, which is coupled to the ground potential through the switch circuit 31. The gate nodes of the NMOS transistors 25 and 26 receive the input signals VIP and VIN, respectively. The positive-feedback circuit includes the PMOS transistors 21 and 22 and the NMOS transistors 23 and 24. The PMOS transistor 21 and the NMOS transistor 23 together constitute a first inverter, and the PMOS transistor 22 and the NMOS transistor 24 together constitute a second inverter. These two inverters are cross-coupled such that the output of each is connected to the input of the other.

As was previously described, the input-stage circuit includes a differential transistor pair including two transistors, and the positive-feedback circuit is a latch circuit including two inverters that are cross-coupled. The use of the differential-pair circuit and the latch circuit enables the use of a simple circuit structure to implement the input-stage circuit and the positive-feedback circuit, thereby enabling the provision of a small-scale dynamic latch comparator.

The input-stage circuit operates in synchronization with the clock signal CLK (see FIG. 1). The input-stage circuit produces two voltages at two respective nodes DN and DP, such that which one of the two voltages is greater than the other is determined by which one of the two input signals VIP and VIN is greater than the other. The positive-feedback circuit operates in synchronization with the clock signal CLK. The positive-feedback circuit performs positive-feedback operations to generate two output signals ON and OP, such that which one of these output signals is greater than the other is responsive to which one of the two voltages at the two respective nodes DN and DP is greater than the other. These two nodes are situated between the latch circuit and the differential pair, and are the connection points between the latch circuit and the differential pair.

The dynamic latch comparator 10 illustrated in FIG. 2 is provided with an adjustment circuit that is electrically connected to the two nodes DN and DP, and that changes, in response to a setting value, the speeds at which the voltages of the two nodes DN and DP change In the example of the circuit illustrated in FIG. 2, the adjustment circuit is the two current-source circuits 32 and 33 that are situated between a predetermined potential (i.e., the ground potential via the switch circuit 31) and the two nodes DN and DP, respectively. The timing control unit 34 adjusts the setting value of the timing control unit 34. Namely, the timing control unit 34 adjusts the amount of electric currents of the current-source circuits 32 and 33. The use of the current-source circuits as an adjustment circuit as described above enables a simple circuit structure to perform reliable control of the speeds at which the voltages of the nodes DN and DP change.

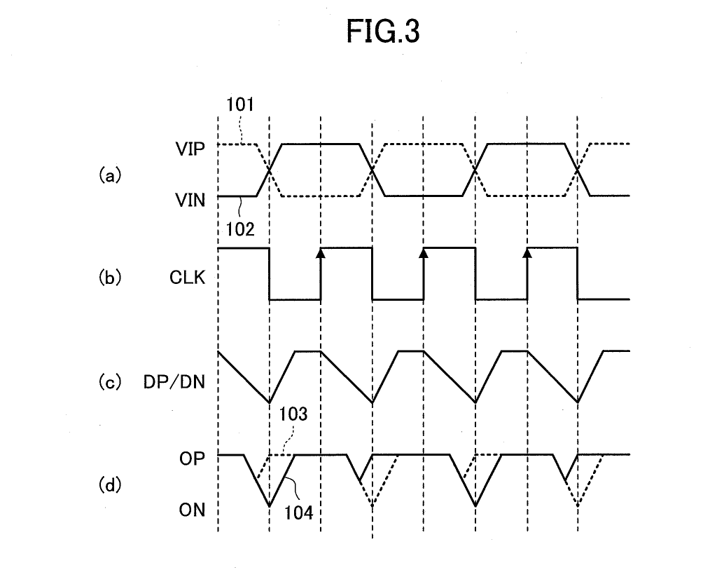

Changing the speeds at which the voltages of the nodes DN and DP change makes it possible to change the time at which the amplification (i.e., regeneration) by the positive-feedback circuit starts. This will be explained in the following with reference to FIG. 2 and FIG. 3.

FIG. 3 is a drawing illustrating an example of the operation of the dynamic latch comparator illustrated in FIG. 2. FIG. 3-(a) depicts a voltage waveform 101 of the input signal VIP and a voltage waveform 102 of the input signal VIN. FIG. 3-(b) depicts a voltage waveform of the clock signal CLK. FIG. 3-(c) depicts a voltage waveform observed at one of the nodes DN and DP that is coupled to the ground potential (i.e., at the same side as where the input signal is High). FIG. 3-(d) depicts a voltage waveform 103 of the output signal OP and a voltage waveform 104 of the output signal ON. In FIG. 3-(a) through FIG. 3-(d), the horizontal axis represents time.

The switch circuits 27 through 30 are conductive for the duration in which the clock signal CLK is Low, so that the output nodes for producing the output signals ON and OP and the two nodes DN and DP are set (i.e., precharged) to High (i.e., power supply voltage VDD). At this time, the switch circuit 31 is nonconductive.

Subsequently, the clock signal CLK changes to High. For the duration in which the clock signal CLK is High, the switch circuits 27 through 30 are nonconductive, and the switch circuit 31 is conductive. During the duration in which the clock signal CLK is High and some duration following thereto, the state in which one of the input signals VIP and VIN is High and the other one is Low preferably continues. When the input signals VIP and VIN are High and Low, respectively, for example, the NMOS transistors 25 and 26 are conductive and nonconductive, respectively. As a result, electric charge of the node DN is discharged to the ground through the NMOS transistor 25 and the switch circuit 31, so that the voltage at the node DN drops from High. Since the NMOS transistor 26 is nonconductive, the electric charge of the node DP is not discharged so that the voltage at the node DP stays at High. In the description given above, the operations of the current-source circuits 32 and 33 are disregarded for the time being.

As the voltage at the node DN drops from High, this voltage at the node DN becomes lower than a transistor threshold voltage Vth below the power supply voltage VDD. When this happens, the NMOS transistor 23 becomes conductive. In response to the conductive state of the NMOS transistor 23, the voltage of the output signal ON changes from High to Low, and, in conjunction therewith, the PMOS transistor 22 changes from the nonconductive state to the conductive state. Namely, the resistance value (i.e., resistance value of the PMOS transistor 22) of the path through which the output signal OP is electrically connected to the power supply voltage VDD decreases, such that the state of the output signal OP gradually approaches a state in which the output signal OP is fixed to the power supply voltage VDD. As the respective connections of the output signals ON and OP to Low and High strengthen, the respective conductive state and nonconductive state of the NMOS transistors 23 and are enhanced, and, also, the respective nonconductive state and conductive state of the PMOS transistors 21 and 22 are enhanced. Namely, as the respective connections of the output signals ON and OP to Low and High strengthen, feedback control operates in such a manner that the respective connections of the output signals ON and OP to Low and High are further reinforced. This positive-feedback operation causes the output signals ON and OP to be latched to Low and High, respectively.

Through the operations as described above, the output signals ON and OP of the dynamic latch comparator 10 exhibit changes as shown by waveforms illustrated in FIG. 3-(d). Specifically, the output signals ON and OP are fixed to High or Low at the end of the low period of the clock signal CLK in accordance with the High or Low states of the input signals VIP and VIN illustrated in FIG. 3-(a) at the timing of rising edges of the clock signal CLK illustrated in FIG. 3-(b).

The dynamic latch comparator 10 illustrated in FIG. 2 includes the current-source circuits 32 and 33 that are capable of changing the amount of electric currents. The current-source circuits 32 and 33 discharge the electric charges of the nodes DN and DP at the speeds responsive to current setting values set by the timing control unit 34, respectively. In so doing, the current setting values of the current-source circuits 32 and 33 may be the same, so that the amount of current flowing through the current-source circuit 32 may be the same as the amount of current flowing through the current-source circuit 33. When the voltages of the nodes DN and DP change in response to the input signals VIP and VIN as described above, the current-source circuits 32 and 33 serve to add a bias to the speed of voltage change by increasing the speed of discharge at these nodes by the same rate as set by the same current setting value. Since the current setting values of the current-source circuits 32 and 33 are the same, the size of the bias to the speed of voltage change is the same between the two nodes DN and DP. There is thus no adverse effect on the operation as to which one of the voltages at the two nodes DN and DP is greater than the other in response to the input signals VIP and VIN.

As was previously described, the positive-feedback circuit starts operating when the voltages of the nodes DN and DP drop from High to become lower than a voltage (which will hereinafter be referred to as a positive-feedback threshold voltage) that is at the transistor threshold voltage Vth below the power supply voltage VDD. Changing the current amount setting of the current-source circuits 32 and 33 enables a change to be made to the time at which the voltages at the nodes DN and DP become lower than the positive-feedback threshold voltage (i.e., as defined with reference to the clock signal CLK). Namely, changing the current amount setting of the current-source circuits 32 and 33 makes it possible to change the time at which the operation of the positive-feedback circuit starts in the temporal axis as defined with reference to the clock signal CLK.

As previously described, the characteristics of the buffer circuits 12 and 13 illustrated in FIG. 1 may vary depending on the process conditions, the operating temperature, the power supply voltage, or the like, so that the timing of edges of the clock signal CLK applied to the dynamic latch comparator 10 may be displaced. The dynamic latch comparator 10 utilizes the control of setting values of the current-source circuits 32 and 33 to change the time at which the operation of the positive-feedback circuit starts relative to the temporal positions of edges of the clock signal CLK. Accordingly, appropriate control of the setting values of the current-source circuits 32 and 33 can ensure that a correct comparison result is produced even when the timing of edges of the clock signal is displaced.

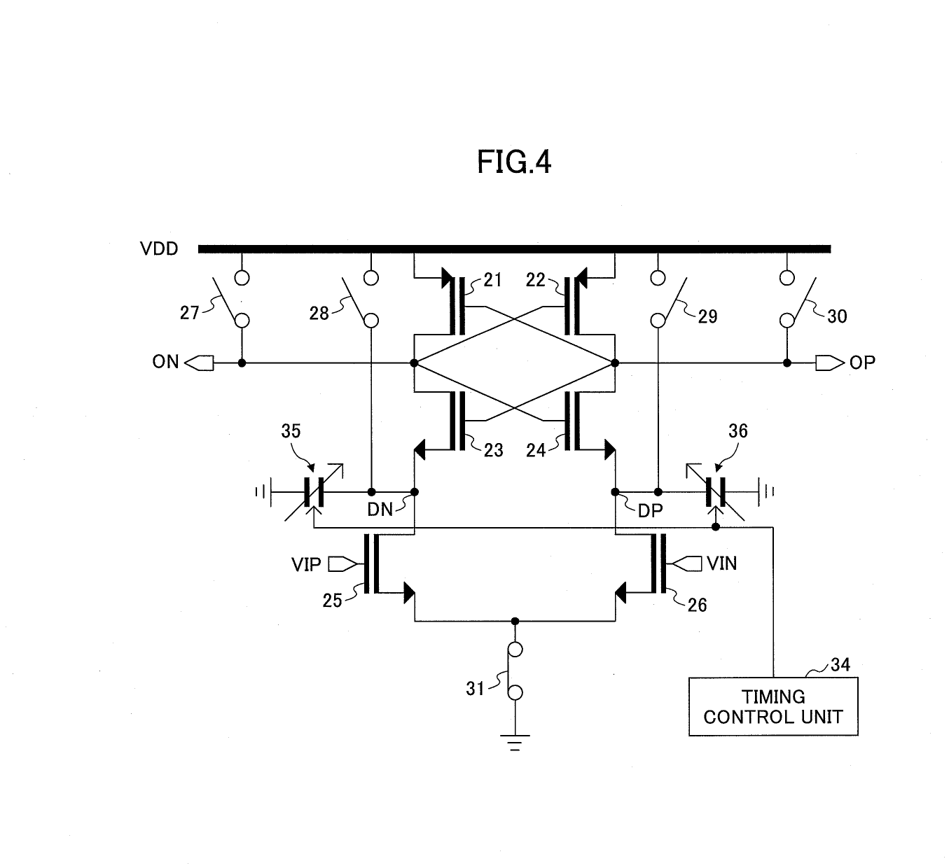

FIG. 4 is a drawing illustrating another example of the configuration of the dynamic latch comparator. In FIG. 4, the same or corresponding elements as those of FIG. 2 are referred to by the same or corresponding numerals, and a description thereof will be omitted as appropriate.

In the dynamic latch comparator 10 illustrated in FIG. 4, variable-capacitance circuits 35 and 36 are provided in place of the current-source circuits 32 and 33 illustrated in FIG. 2. Similarly to the circuit configuration illustrated in FIG. 2, the dynamic latch comparator 10 is provided with an adjustment circuit that is electrically connected to the two nodes DN and DP, and that changes, in response to a setting value, the speed at which the voltages of the two nodes DN and DP change In the example of the circuit illustrated in FIG. 4, the adjustment circuit is the two variable-capacitance circuits 35 and 36 that are situated between a predetermined potential (i.e., the ground potential) and the two nodes DN and DP, respectively. The timing control unit 34 adjusts the respective capacitance values of the two variable-capacitance circuits 35 and 36.

The variable-capacitance circuits 35 and may be variable-capacitance elements such as varactors. Alternatively, the variable-capacitance circuits 35 and 36 may include a plurality of capacitance elements having fixed capacitance values and connected to each other in parallel, and may further include switch circuits series-connected to these capacitance elements, respectively. In such a case, the number of the switch circuits set in the conductive state may be changed to adjust the capacitance values of the variable-capacitance circuits 35 and 36.

The variable-capacitance circuits 35 and 36 serve to make the slope of voltage change at the nodes DN and DP increasingly gentle as the capacitance setting value set by the timing control unit 34 increases. The capacitance setting values of the variable-capacitance circuits 35 and 36 may be the same. When the voltages of the nodes DN and DP change in response to the input signals VIP and VIN as previously described, the variable-capacitance circuits 35 and 36 serve to add the same bias to the speeds of voltage change at these nodes. Since the capacitance setting values of the variable-capacitance circuits 35 and 36 are the same, the size of the bias to the speed of voltage change is the same between the two nodes DN and DP. There is thus no adverse effect on the operation as to which one of the voltages at the two nodes DN and DP is greater than the other in response to the input signals VIP and VIN.

As was previously described, the positive-feedback circuit starts operating as the voltages at the nodes DN and DP drop from High to become lower than the positive-feedback threshold voltage. Changing the capacitance value setting of the variable-capacitance circuits 35 and 36 enables a change to be made to the time at which the voltages at the nodes DN and DP become lower than the positive-feedback threshold voltage (i.e., as defined with reference to the clock signal CLK). Namely, changing the capacitance value setting of the variable-capacitance circuits 35 and 36 makes it possible to change the time at which the operation of the positive-feedback circuit starts in the temporal axis as defined with reference to the clock signal CLK.

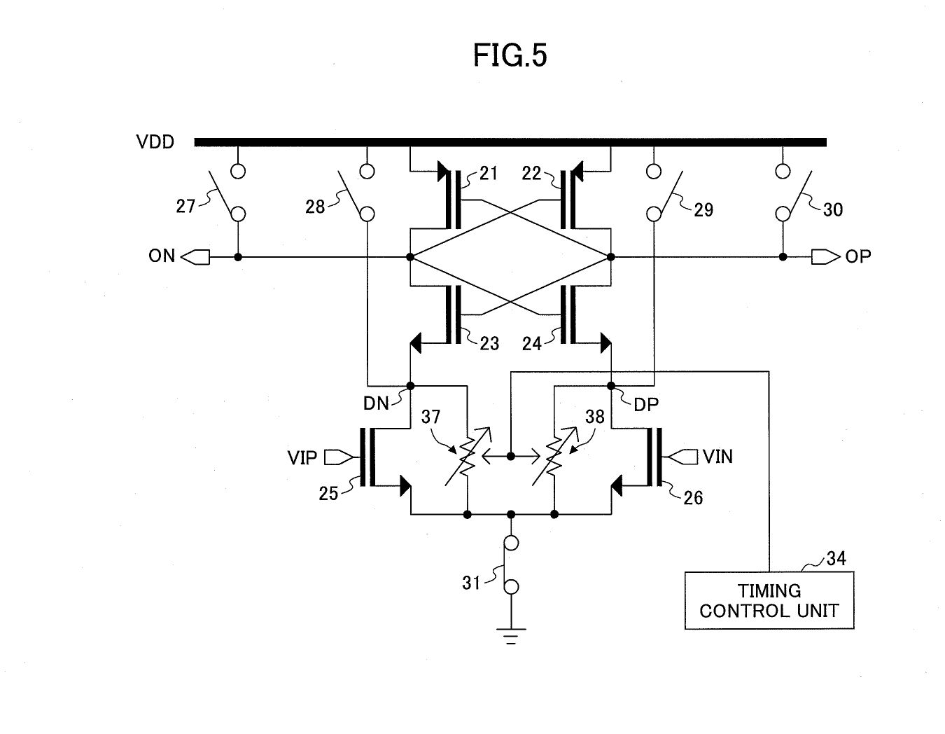

FIG. 5 is a drawing showing yet another example of the configuration of the dynamic latch comparator. In FIG. 5, the same or corresponding elements as those of FIG. 2 are referred to by the same or corresponding numerals, and a description thereof will be omitted as appropriate.

In the dynamic latch comparator 10 illustrated in FIG. 5, variable-resistance circuits 37 and 38 are provided in place of the current-source circuits 32 and 33 illustrated in FIG. 2. Similarly to the circuit configuration illustrated in FIG. 2, the dynamic latch comparator 10 is provided with an adjustment circuit that is electrically connected to the two nodes DN and DP, and that changes, in response to a setting value, the speed at which the voltages of the two nodes DN and DP change In the example of the circuit illustrated in FIG. 4, the adjustment circuit is the two variable-resistance circuits 37 and 38 that are situated between a predetermined potential (i.e., the ground potential via the switch circuit 31) and the two nodes DN and DP, respectively. The timing control unit 34 adjusts the respective resistance values of the two variable-resistance circuits 37 and 38.

The variable-resistance circuits 37 and 38 may include a plurality of resistance elements having fixed resistance values and connected to each other in parallel, and may further include switch circuits series-connected to these resistance elements, respectively. The number of the switch circuits set in the conductive state may be changed to adjust the resistance values of the variable-resistance circuits 37 and 38.

The variable-resistance circuits 37 and 38 serve to increase the speed of discharge from the nodes DN and DP as the resistance setting value set by the timing control unit 34 decreases. The resistance setting values of the variable-resistance circuits 37 and 38 may be the same. When the voltages of the nodes DN and DP change in response to the input signals VIP and VIN as previously described, the variable-resistance circuits 37 and serve to add the same bias to the speeds of voltage change at these nodes. Since the resistance setting values of the variable-resistance circuits 37 and 38 are the same, the size of the bias to the speed of voltage change is the same between the two nodes DN and DP. There is thus no adverse effect on the operation as to which one of the voltages at the two nodes DN and DP is greater than the other in response to the input signals VIP and VIN.

As was previously described, the positive-feedback circuit starts operating as the voltages at the nodes DN and DP drop from High to become lower than the positive-feedback threshold voltage. Changing the resistance value setting of the variable-resistance circuits 37 and 38 enables a change to be made to the time at which the voltages at the nodes DN and DP become lower than the positive-feedback threshold voltage (i.e., as defined with reference to the clock signal CLK). Namely, changing the resistance value setting of the variable-resistance circuits 37 and 38 makes it possible to change the time at which the operation of the positive-feedback circuit starts in the temporal axis as defined with reference to the clock signal CLK.

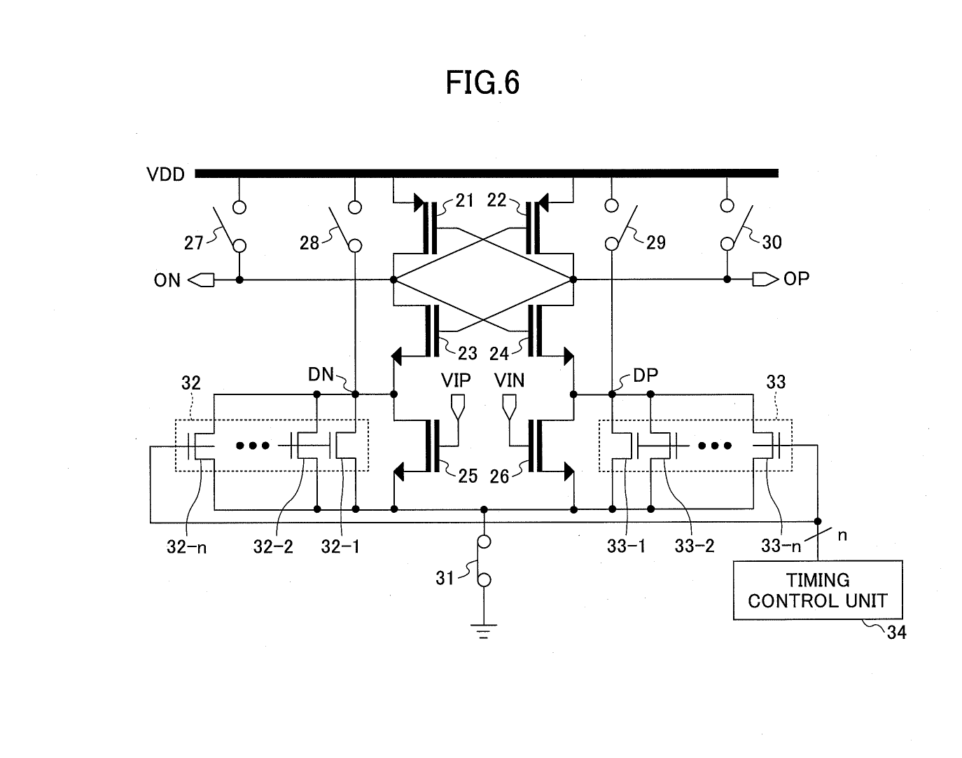

FIG. 6 is a drawing illustrating an example of a more specific configuration of the dynamic latch comparator illustrated in FIG. 2. In FIG. 6, the same or corresponding elements as those of FIG. 2 are referred to by the same or corresponding numerals, and a description thereof will be omitted as appropriate.

In the dynamic latch comparator 10 illustrated in FIG. 6, each of the current-source circuits 32 and 33 includes a plurality of NMOS transistors connected in parallel. The current-source circuit 32 includes n NMOS transistors 32-1 through 32-n that are connected to each other in parallel between the node DN and the switch circuit 31. The current-source circuit 33 includes n NMOS transistors 33-1 through 33-n that are connected to each other in parallel between the node DP and the switch circuit 31. The timing control unit 34 applies High to the gate nodes of a desired number of NMOS transistors among the n NMOS transistors of each of the current-source circuits 32 and 33, and applies Low to the remaining NMOS transistors. The timing control unit 34 adjusts the number of NMOS transistors to which High is applied (i.e., the number of NMOS transistors that are conductive), thereby setting the electric currents flowing through the current-source circuits 32 and 33 to desired values.

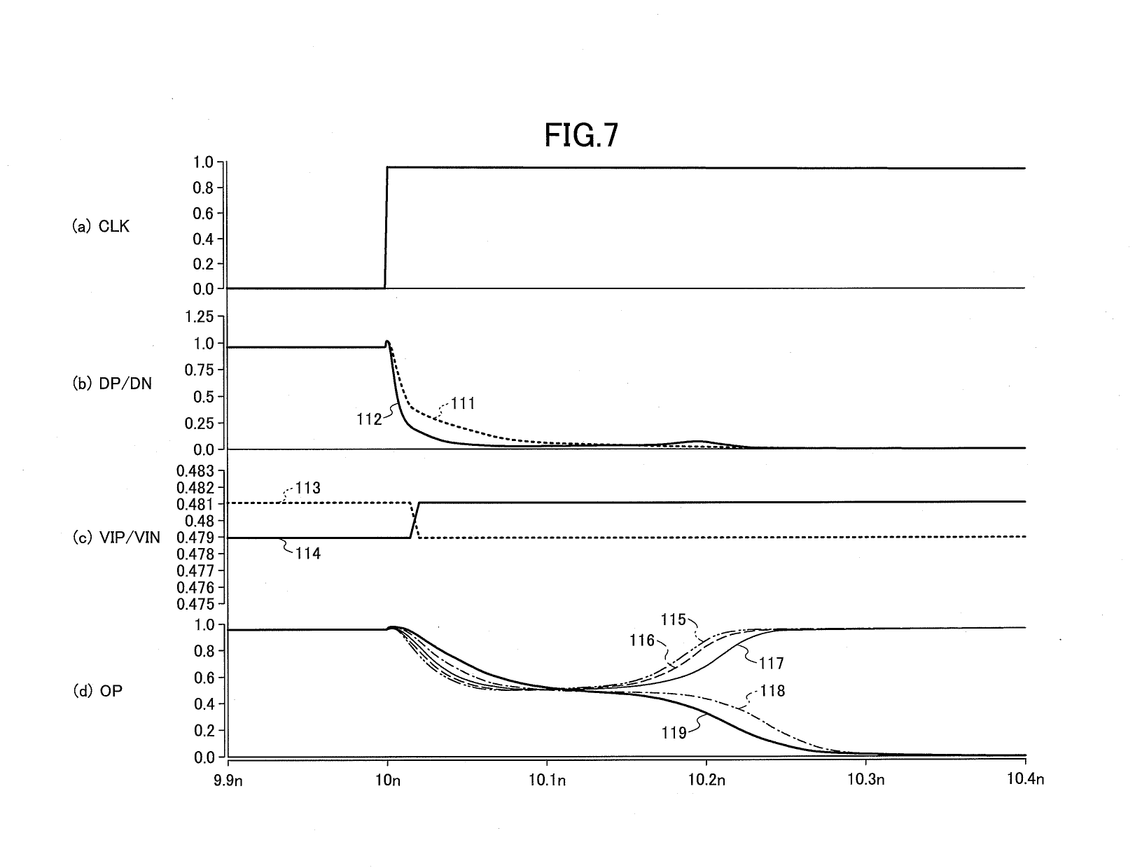

FIG. 7 is a drawing illustrating an example of the operation of the dynamic latch comparator illustrated in FIG. 6. FIG. 7-(a) depicts a voltage waveform of the clock signal CLK. FIG. 7-(b) depicts a voltage waveform observed at one of the nodes DN and DP that is coupled to the ground potential (i.e., at the same side as where the input signal is High). FIG. 7-(c) depicts a voltage waveform 113 of the input signal VIP and a voltage waveform 114 of the input signal VIN. FIG. 7-(d) depicts a voltage waveform of the output signal OP. In FIG. 7-(a) through FIG. 7-(d), the horizontal axis represents time. The waveforms illustrated in FIG. 7-(a) through FIG. 7-(d) are obtained by a computer simulation that simulates the operation of the dynamic latch comparator 10.

After the clock signal CLK changes from Low to High, a state change occurs from the state in which the input signals VIP and VIN are High and Low, respectively, to the state in which the input signals VIP and VIN are Low and High, respectively. In the signal waveforms illustrated in FIG. 7, the relative positional relationship between the point of change of the clock signal CLK and the point of change of the input signals VIP and VIN is fixed, and does not change. However, the timing control unit 34 in the dynamic latch comparator 10 illustrated in FIG. 6 changes the number of conductive NMOS transistors in the current-source circuits 32 and 33, thereby changing the time at which the amplification operation of the positive-feedback circuit starts.

In FIG. 7-(b), a voltage waveform 111 is the voltage waveform of one of the nodes DN and DP situated on the same side as where the input signal is High as observed when the number of conductive NMOS transistors are zero in each of the current-source circuits 32 and 33. Further, a voltage waveform 112 is the voltage waveform of one of the nodes DN and DP situated on the same side as where the input signal is High as observed when the number of conductive NMOS transistors are four in each of the current-source circuits 32 and 33. Here, one of the nodes DN and DP situated on the same side as where the input signal is High refers to the side on which the input signal is High at the time of a transition of the clock signal CLK. In the timing relationship illustrated in FIG. 7, this side refers to the DP side (i.e., VIP side).

The voltage at the node DP drops faster in the case of the number of conductive NMOS transistors being four than in the case of such a number being zero. Accordingly, the feedback operation of the positive-feedback circuit starts earlier in the case of the number of conductive NMOS transistors being four than in the case of such a number being zero.

As illustrated in FIG. 7-(a) and FIG. 7-(c), the input signal VIP is High at the time of the transition of the clock signal CLK. The dynamic latch comparator 10 will thus have the output signal OP being High and the output signal ON being Low. In the example of the operation illustrated in FIG. 7-(a) and FIG. 7-(c), however, the magnitude relationship between the input signals VIP and VIN is reversed immediately after the transition of the clock signal CLK. In the case of the number of conductive transistors being zero in each of the current-source circuits 32 and 33, a late start of the feedback operation of the positive-feedback circuit causes the output signals to be determined by the signal state observed after the reversal of the magnitude relationship between the input signals VIP and VIN, i.e., by the signal state in which the input signal VIN is High. In FIG. 7-(d), the output signal OP as observed in the case of the number of conductive transistors being zero in the current-source circuits 32 and 33 is illustrated as a voltage waveform 119. Despite the fact that the output signal OP is expected to be High as previously described, the output signal OP ends up being set to Low in the case of the number of conductive transistors being zero in the current-source circuits 32 and 33.

In FIG. 7-(d), voltage waveforms 115 through 118 represent the voltage of the output signal OP as observed in the case of the number of conductive transistors being four through one, respectively, in each of the current-source circuits 32 and 33. When the number of conductive transistors is one, the output signal OP is still set to Low as illustrated in the voltage waveform 118. As the number of conductive transistors is increased, however, the start time of the feedback operation of the positive-feedback circuit becomes increasingly early, so that the positive-feedback circuit can detect the signal state prior to the reversal of the magnitude relationship between the input signals VIP and VIN. As illustrated in the voltage waveforms 115 through 117, the output signal OP is set to High in the case of the number of conductive transistors being four through two, respectively.

In the manner as described above, the dynamic latch comparator 10 illustrated in FIG. 6 has the timing control unit 34 that controls the number of conductive transistors in the current-source circuits 32 and 33, thereby controlling the final detection values of the output signals ON and OP. Namely, even though the relative positional relationship between the point of the transition of the clock signal CLK and the point of the transition of the input signals VIP and VIN remains the same, a change in the start time of the feedback operation of the positive-feedback circuit serves to change the timing of detection of the input signals, thereby changing the detection values of the output signals. Conversely, even when the phase of the clock signal CLK is displaced depending on the process conditions, the operating temperature, the power supply voltage, or the like, the control performed by the timing control unit 34 ensures that the comparator produces a correct comparison result (i.e., correct detection result).

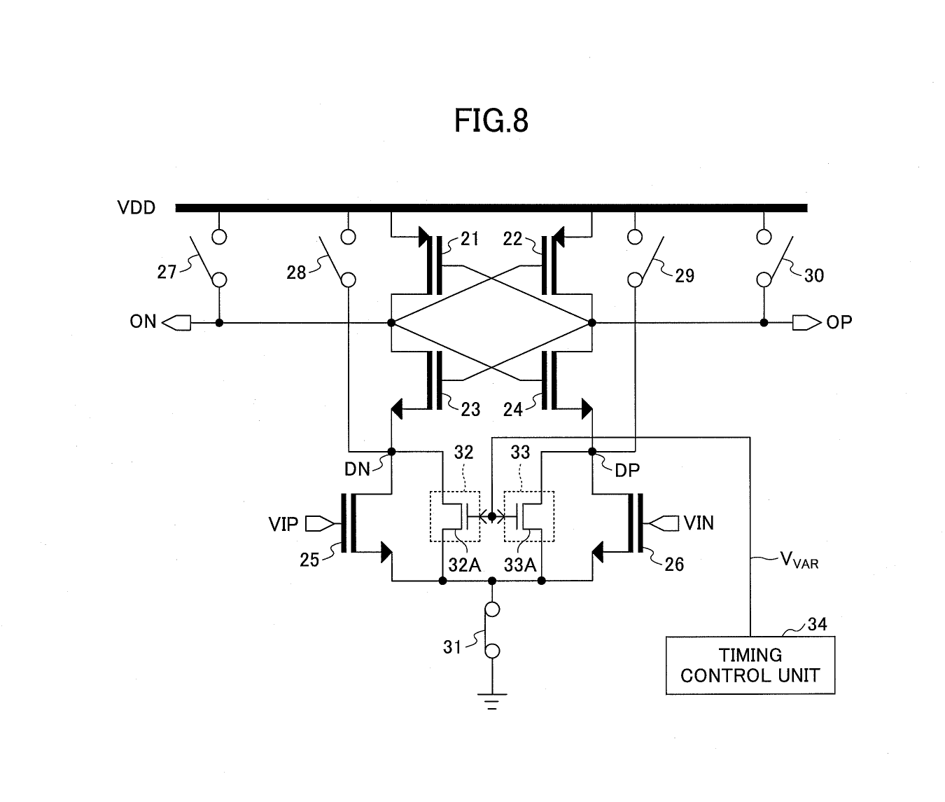

FIG. 8 is a drawing illustrating another example of a more specific configuration of the dynamic latch comparator illustrated in FIG. 2. In FIG. 8, the same or corresponding elements as those of FIG. 2 are referred to by the same or corresponding numerals, and a description thereof will be omitted as appropriate.

In the dynamic latch comparator 10 illustrated in FIG. 8, each of the current-source circuits 32 and 33 includes a single NMOS transistor. The current-source circuit 32 includes a single NMOS transistor 32A situated between the node DN and the switch circuit 31. The current-source circuit 33 includes a single NMOS transistor 33A situated between the node DP and the switch circuit 31. The timing control unit 34 applies a desired voltage to the gate node of the single NMOS transistor in each of the current-source circuits 32 and 33. The timing control unit 34 adjusts a voltage level applied to the gate node of the NMOS transistor, thereby setting the electric currents flowing through the current-source circuits 32 and 33 to desired values.

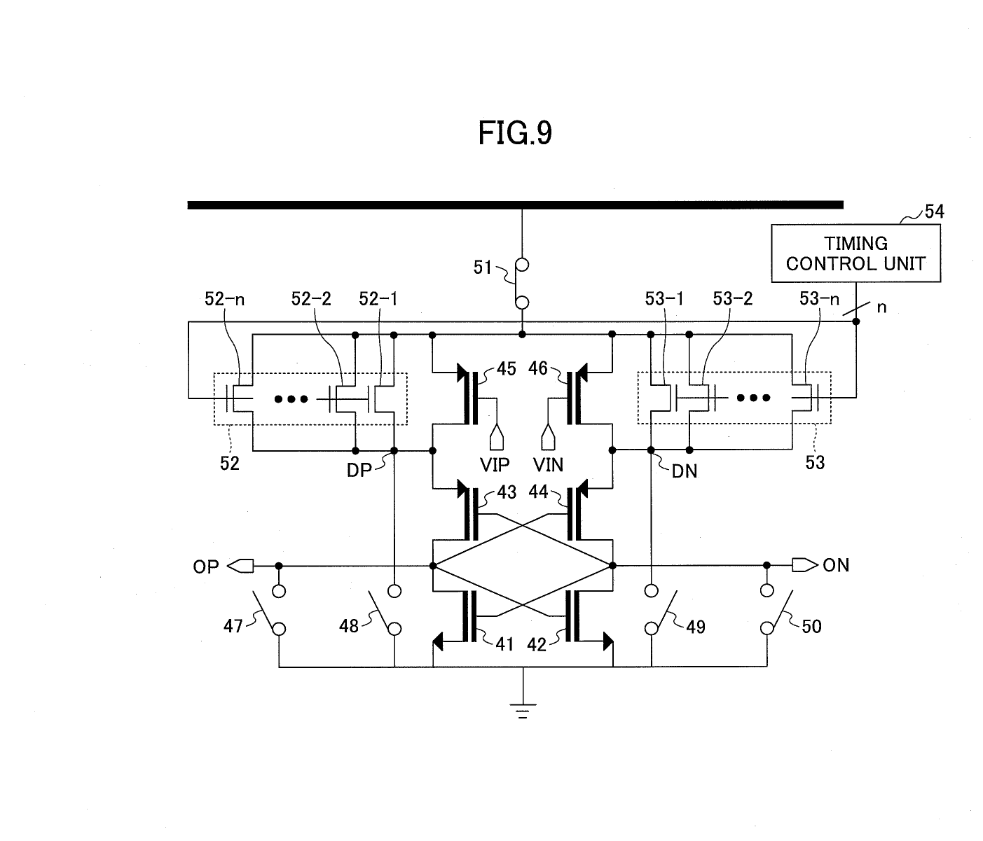

FIG. 9 is a drawing illustrating another example of the configuration of the dynamic latch comparator. The dynamic latch comparator 10 illustrated in FIG. 9 includes NMOS transistors 41 and 42, PMOS transistors 43 through 46, switch circuits 47 through 51, current-source circuits 52 and 53, and a timing control unit 54. The switch circuits 47 through 50 become conductive in the case of the clock signal CLK (see FIG. 1) being High, and become nonconductive in the case of the clock signal CLK being Low. The switch circuit 51 becomes nonconductive in the case of the clock signal CLK being High, and becomes conductive in the case of the clock signal CLK being Low. The switch circuits 47 through 50 may be NMOS transistors, for example, and the switch circuit 51 may be an PMOS transistor, for example.

In the dynamic latch comparator 10 illustrated in FIG. 9, each of the current-source circuits 52 and 53 includes a plurality of PMOS transistors connected in parallel. The current-source circuit 52 includes n PMOS transistors 52-1 through 52-n that are connected to each other in parallel between the node DP and the switch circuit 51. The current-source circuit 53 includes n PMOS transistors 53-1 through 53-n that are connected to each other in parallel between the node DN and the switch circuit 51. The timing control unit 54 applies Low to the gate nodes of a desired number of PMOS transistors among the n PMOS transistors of each of the current-source circuits 52 and 53, and applies High to the remaining PMOS transistors. The timing control unit 54 adjusts the number of PMOS transistors to which Low is applied (i.e., the number of PMOS transistors that are conductive), thereby setting the electric currents flowing through the current-source circuits 52 and 53 to desired values.

The dynamic latch comparator 10 illustrated in FIG. 9 has changes made relative to the configuration illustrated in FIG. 6 such that PMOS transistors and NMOS transistors are replaced with NMOS transistors and PMOS transistors, respectively, and the power supply voltage VDD and the ground voltage are swapped over. Even if the polarity of the circuit is reversed with respect to the dynamic latch comparator as described above, a resulting dynamic latch comparator operates similarly and produces similar advantages to the dynamic latch comparator 10 illustrated in FIG. 6.

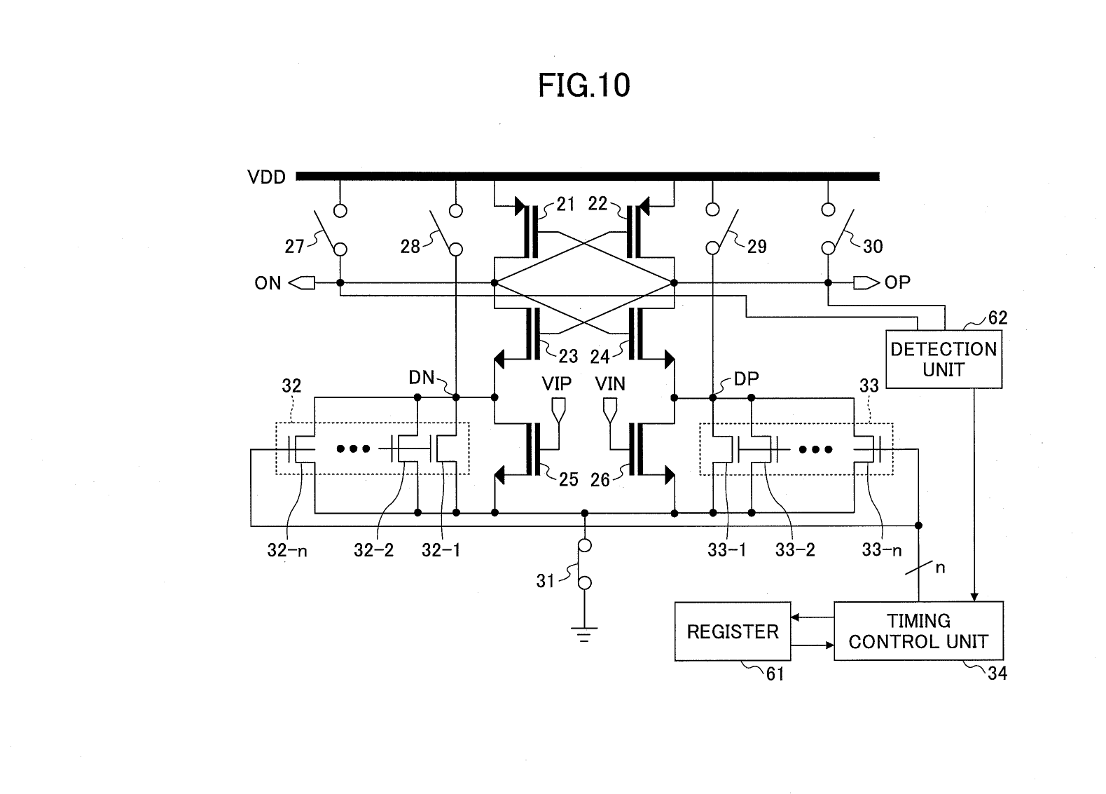

FIG. 10 is a drawing illustrating an example of the configuration of the dynamic latch comparator that performs calibration. In FIG. 10, the same or corresponding elements as those of FIG. 6 are referred to by the same or corresponding numerals, and a description thereof will be omitted as appropriate.

The circuit illustrated in FIG. 10 has a register (memory) 61 and a detection unit (latch) 62 as additional elements relative to the circuit illustrated in FIG. 6. The detection unit 62 operates in synchronization with the clock signal CLK (see FIG. 1), and latches the output signals ON and OP of the dynamic latch comparator 10 at the falling edges of the clock signal CLK. Namely, the output signals ON and OP produced by the dynamic latch comparator 10 as the results of comparison of the input signals VIP and VIN are stored in the detection unit 62 as the detection results. The detection results stored in the detection unit 62 are supplied to the timing control unit 34. The register 61 stores the current setting values of the current-source circuits 32 and 33. The timing control unit 34 is coupled to the register 61. The timing control unit 34 may store in the register 61 a current setting value that is determined by a calibration procedure which will be described later, and may access the current setting value stored in the register 61.

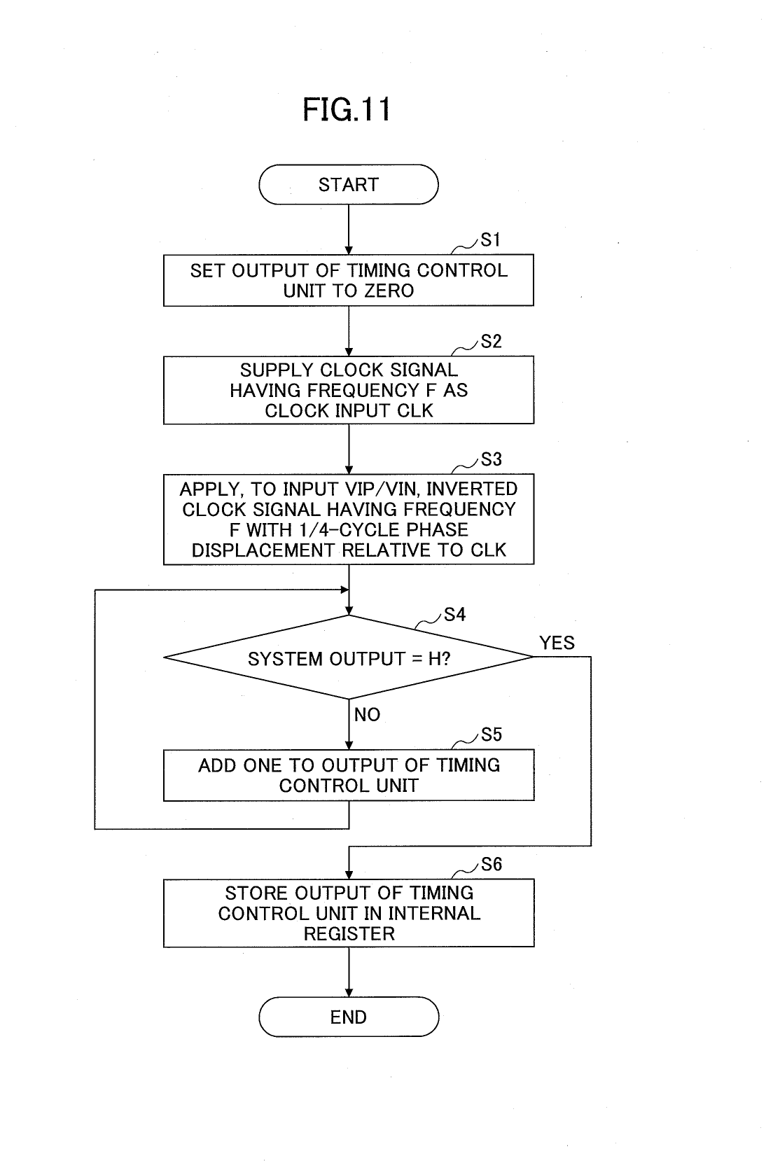

FIG. 11 is a drawing illustrating an example of the calibration operation of the dynamic latch comparator. The calibration operation may be performed by the timing control unit 34 in the circuit illustrated in FIG. 10.

It may be noted that, in FIG. 11, an order in which the steps illustrated in the flowchart are performed is only an example. The scope of the disclosed technology is not limited to the disclosed order. For example, a description may explain that an A step is performed before a B step is performed. Despite such a description, it may be physically and logically possible to perform the B step before the A step while it is possible to perform the A step before the B step. In such a case, all the consequences that affect the outcomes of the flowchart may be the same regardless of which step is performed first. It then follows that, for the purposes of the disclosed technology, it is apparent that the B step can be performed before the A step is performed. Despite the explanation that the A step is performed before the B step, such a description is not intended to place the obvious case as described above outside the scope of the disclosed technology. Such an obvious case inevitably falls within the scope of the technology intended by this disclosure.

In step S1, the timing control unit 34 sets the setting output value thereof to zero. The setting output value of the timing control unit 34 may be the current setting value, which may be, in this example, a value indicative of the number of conductive NMOS transistors in each of the current-source circuits 32 and 33. Namely, in the case of the setting output value of the timing control unit 34 being zero, the number of conductive transistors is zero in each of the current-source circuits 32 and 33.

In step S2, a clock signal having frequency F that is generated by the clock generating circuit described in connection with FIG. 1 is applied to the dynamic latch comparator 10 as the clock signal CLK under the control of the timing control unit 34. Alternatively, the clock signal may be supplied to the dynamic latch comparator 10 from outside the electronic circuit.

In step S3, the clock signal having frequency F and the signal having the reversed phase thereof (i.e., inverted signal) are applied to the dynamic latch comparator as the input signals VIP and VIN. These input signals are applied to the dynamic latch comparator 10 under the same conditions as when the true input signals VIP and VIN are applied, but have the same waveform patterns as the clock signal having frequency F. These signals may be supplied to the dynamic latch comparator from inside the electronic circuit, or may be supplied to the dynamic latch comparator from outside the electronic circuit. As a general principle, the signal source of the true input signals VIP and VIN may generate the clock signal having frequency F and the inverted signal thereof, which may then be applied to the dynamic latch comparator. Even if the same signal source is not used, it suffices for the clock signal having frequency F and the inverted signal thereof to be applied to the dynamic latch comparator under the substantially same conditions (i.e., phase conditions, voltage conditions, waveform distortion conditions, etc.) as those of the true input signals VIP and VIN.

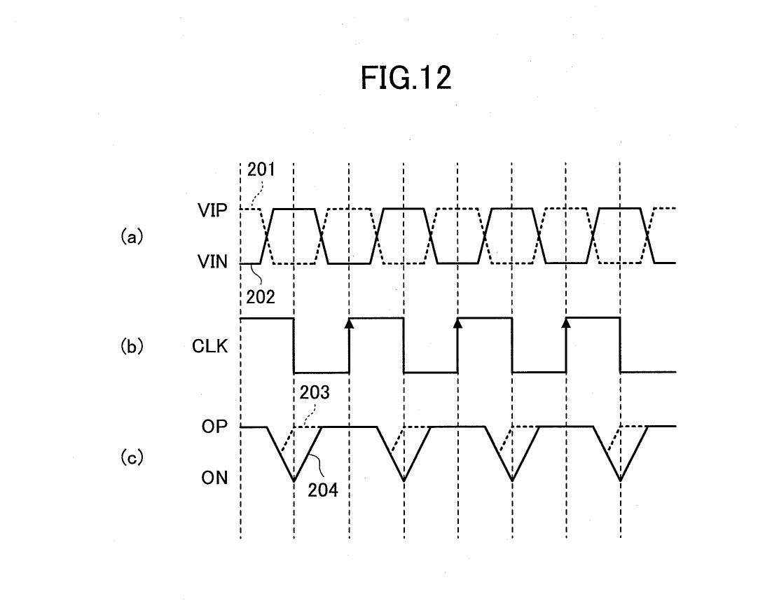

FIG. 12 is a drawing illustrating an example of input signals at the time of calibration. FIG. 12-(a) depicts a voltage waveform 201 of the input signal VIP and a voltage waveform 202 of the input signal VIN. FIG. 12-(b) depicts a voltage waveform of the clock signal CLK. FIG. 12-(c) depicts a voltage waveform 203 of the output signal OP and a voltage waveform 204 of the output signal ON. In FIG. 12-(a) through FIG. 12-(c), the horizontal axis represents time. In this example, the input signals VIP and VIN have a phase displacement of a ¼ cycle relative to the clock signal CLK, which is an ideal condition, so that the detection result (i.e., the result stored in the detection unit 62 of FIG. 10) of the output signal OP is always High. In step S3 of FIG. 11, it suffices that the clock signal having frequency F and the inverted signal thereof are applied relative to the signals at the gate nodes of the NMOS transistors 25 and 26 such that the output signal OP will always be High, for example.

Referring to FIG. 11 again, in step S4, the timing control unit 34 checks whether the output of the system (i.e., the value stored in the detection unit 62) is High. In the case of the output of the system being not High, i.e., in the case of the obtained detection value being different from the expected detection value, the timing control unit 34 adds “1” to the setting output value thereof (i.e., the number of conductive NMOS transistors in the current-source circuits 32 and 33) in step S5. Thereafter, the procedure returns to step S4, from which the subsequent steps are repeated.

When the check in step S4 indicates that the output of the system is High, the timing control unit 34 stores the setting output value as used at present in the register 61 in step S6. With this, the calibration procedure comes to an end.

In the example of the calibration operation illustrated in FIG. 11, the setting output value of the timing control unit 34 is immediately stored in the register 61 upon finding that the output of the system is High or upon the change of the output of the system from Low to High. Alternatively, a sufficiently stable comparison operation (i.e., detection operation) of the dynamic latch comparator may be ensured by storing in the register 61 a setting output value that differs by some margin from the setting output value that is used at the point of change in the output of the system between High and Low. For example, with the knowledge that the frequency of the clock signal CLK is F, and with setting output value k being that of the point of change described above, value m may be known such that setting output value k+m is a next one of such a point of change. In such a case, m/2 or an integer value closest thereto may be added to the setting output value obtained by the procedure of FIG. 11, and the result of such an addition operation may be stored in the register 61. Alternatively, the setting output value is increased one by one from 0 to n (i.e., the number of NMOS transistors disposed in each of the current-source circuits 32 and 33), and the points of change as described above are detected through such stepwise increases. A setting output value corresponding to the midpoint between the points of change may be stored in the register 61.

According to at least one embodiment, a dynamic latch comparator produces a correct comparison result even when the edge timing of the clock signal is displaced.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A comparator, comprising:
an input-stage circuit configured to operate in synchronization with a clock signal and to produce two voltages at two nodes, respectively, such that which one of the two voltages is greater than the other is responsive to which one of two input signals is greater than the other;
a positive-feedback circuit configured to operate in synchronization with the clock signal and to produce, through positive feedback, two output signals responsive to which one of the two voltages at the two nodes is greater than the other; and
an adjustment circuit coupled to the two nodes, and configured to change, in response to a setting value, speed at which voltages at the two nodes change.

2. The comparator as claimed in claim 1, wherein the adjustment circuit includes two current-source circuits situated between a predetermined potential and the two nodes, respectively, and amounts of electric currents flowing through the two current-source circuits are adjusted.

3. The comparator as claimed in claim 1, wherein the adjustment circuit includes two capacitance circuits situated between a predetermined potential and the two nodes, respectively, and capacitance values of the two capacitance circuits are adjusted.

4. The comparator as claimed in claim 1, wherein the adjustment circuit includes two resistance circuits situated between a predetermined potential and the two nodes, respectively, and resistance values of the two resistance circuits are adjusted.

5. The comparator as claimed in claim 1, wherein the input-stage circuit includes a differential pair constituted by two transistors, and the positive-feedback circuit includes a latch circuit including two cross-coupled inverters, wherein the two nodes are situated between the differential pair and the latch circuit.

6. An electronic circuit, comprising:
a comparator; and
a core circuit configured to receive output signals of the comparator,
wherein the comparator includes:
an input-stage circuit configured to operate in synchronization with a clock signal and to produce two voltages at two nodes, respectively, such that which one of the two voltages is greater than the other is responsive to which one of two input signals is greater than the other;
a positive-feedback circuit configured to operate in synchronization with the clock signal and to produce, through positive feedback, two output signals responsive to which one of the two voltages at the two nodes is greater than the other; and
an adjustment circuit coupled to the two nodes, and configured to change, in response to a setting value, speed at which voltages at the two nodes change; and
a timing control unit configured to adjust the setting value for the adjustment circuit.

7. A method of controlling a comparator, which includes an input-stage circuit configured to operate in synchronization with a clock signal and to produce two voltages at two nodes, respectively, such that which one of the two voltages is greater than the other is responsive to which one of two input signals is greater than the other, a positive-feedback circuit configured to operate in synchronization with the clock signal and to produce, through positive feedback, two output signals responsive to which one of the two voltages at the two nodes is greater than the other, and an adjustment circuit coupled to the two nodes, and configured to change, in response to a setting value, speed at which voltages at the two nodes change, the method comprising:
causing the two input signals to alternate between High and Low at frequency equal to a frequency of the clock signal; and
adjusting the setting value in response to the two output signal.
